(19) United States
(12) Patent Application Publication
(10) Pub. No.: US 2014/0283904 A1
(43) Pub. Date: Sep. 25, 2014

(54) Solar Cell of Anti Potential Induced Degradation and Manufacturing Method Thereof

(71) Applicant: Jinksolar Hoding Co., LTD, Jiangxi (CN)

(72) Inventors: Jide Huang, Jiangxi (CN); Fangdan Jiang, Jiangxi (CN); Hao Jin, Jiangxi (CN); Kangping Chen, Jiangxi (CN)

(21) Appl. No.: 13/935,131

(22) Filed: Jul. 3, 2013

(30) Foreign Application Priority Data
Mar. 21, 2013 (CN) 201310092404.3

(51) Int. Cl. H01L 31/0216; H01L 31/18

(52) U.S. Cl. CPC H01L 31/02168; H01L 31/18
USPC 136/256; 438/72

(57) ABSTRACT

A solar cell of anti potential induced degradation and a manufacturing method thereof are disclosed by embodiments of the invention. The method includes: performing plasma cleaning on a silicon wafer by using an oxidizing gas, so as to form a first silicon oxide film on the surface of the silicon wafer; and forming an anti-reflection film on the surface of the first silicon oxide film, where the anti-reflection film includes at least a silicon oxide film.

### RELATED APPLICATIONS

The present application claims the priority of Chinese Patent Application No. 201310092404.3, titled “SOLAR CELL OF ANTI POTENTIAL INDUCED DEGRADATION AND MANUFACTURING METHOD THEREOF”, filed with the Chinese State Intellectual Property Office on Mar. 21, 2013, the entire disclosure of which is incorporated herein by reference.

### FIELD OF THE INVENTION

The present invention relates to the technical field of solar cell manufacturing, and in particular to a solar cell of anti potential induced degradation and a manufacturing method thereof.

### BACKGROUND OF THE INVENTION

Solar energy is clean energy. The photovoltaic module is an apparatus for converting light energy into electrical energy by utilizing photovoltaic effect of the PN junction of silicon material. The photovoltaic module includes: a glass backboard and a glass substrate which are arranged oppositely; a solar cell arranged between the glass backboard and the glass substrate; a packaging frame for fixing the glass backboard, the solar cell and the glass substrate; and so on.

The conventional processes for manufacturing the solar cell include processes such as texturing, diffusion, etching, chemical vapor deposition (i.e., PECVD), screen printing and sintering. In the texturing process, the surface of the silicon wafer is eroded by using acid or alkali to form different surface patterns, i.e., surface texturization, therefore the light reflectance is reduced, the short-circuit current is increased and the photoelectric conversion efficiency of the solar cell is ultimately improved. In the diffusion process, the impurity diffusion is performed on the silicon wafer to form a PN junction, which acts as a “heart” of the semiconductor device when the semiconductor device operates. In the etching process, the P-type region and N-type region of the silicon wafer are separated from each other. In the PECVD process, the gas containing the atom which composes the film is ionized by using microwave or radio frequency, to form plasma which has strong chemical activity and is prone to chemical reaction, so that a desired anti-reflection film is deposited on the surface of the silicon wafer. In the screen printing process, by using the adhesive tape on the printing blade, slurry is moved through a screen template with an image or a pattern, to print on the surface of the silicon wafer and form a printed electrode. In the sintering process, the organic component in the slurry is burnt out, so that a good ohmic contact is formed between the slurry and the silicon wafer.

However, in the photovoltaic module manufactured by using the existing solar cell manufacturing processes, a potential induced degradation (referred to as PID for short) effect is prone to occur. That is, the photovoltaic module operates under a high negative voltage for a long time, so there will be a leakage current passage between the glass substrate and the package material. Therefore, a large number of charges are accumulated on the surface of the solar cell, and the charges accumulated on the surface of the solar cell may draw photogenic charge carriers, leading to leakage current. Therefore, electrical performance parameters of the photovoltaic module, such as the fill factor FF, the short circuit current Jsc and the open circuit voltage Voc are deteriorated, and thus the electrical performance of the photovoltaic module will be lower than the design criteria.

### SUMMARY OF THE INVENTION

In order to solve the above-mentioned technical problem, a solar cell of anti potential induced degradation and a manufacturing method thereof are provided according to embodiments of the invention. The solar cell manufactured by using the manufacturing method has a good electrical insulation property with outside packaging material and the glass substrate, so the corresponding photovoltaic module has an anti potential induced degradation effect, which improves the electrical performance of the photovoltaic module operating under the high negative voltage for a long time.

In order to solve the above-mentioned problem, following technical solutions are provided according to embodiments of the invention.

A method for manufacturing a solar cell of anti potential induced degradation includes: performing plasma cleaning on a silicon wafer by using an oxidizing gas, so as to form a first silicon oxide film on the surface of the silicon wafer; and forming an anti-reflection film on the surface of the first silicon oxide film, where the anti-reflection film includes at least a silicon oxide film.

Preferably, the oxidizing gas includes at least one of NH3 and N2O.

Preferably, the plasma cleaning lasts for 30 s to 900 s, inclusive.

Preferably, the forming an anti-reflection film on the surface of the first silicon oxide film includes: depositing a uniform silicon oxide film on the surface of the first silicon oxide film, so as to form the anti-reflection film.

Preferably, the forming an anti-reflection film on the surface of the first silicon oxide film includes: depositing a uniform silicon oxide film on the surface of the first silicon oxide film, and depositing a uniform silicon nitride film on the surface of the silicon oxide film, so as to form the anti-reflection film.

Preferably, the forming an anti-reflection film on the surface of the first silicon oxide film includes: depositing a uniform silicon nitride film on the surface of the first silicon oxide film, and depositing a uniform silicon oxide film on the surface of the silicon nitride film, so as to form the anti-reflection film.

Preferably, the forming an anti-reflection film on the surface of the first silicon oxide film includes: depositing a uniform silicon oxide film on the surface of the first silicon oxide film, depositing a uniform silicon nitride film on the surface of the silicon oxide film, and depositing a uniform silicon oxide film on the surface of the silicon nitride film, so as to form the anti-reflection film.

Preferably, the silicon oxide film in the anti-reflection film is deposited by using a method of PECVD, APCVD or LPCVD.

Preferably, the silicon oxide film in the anti-reflection film is formed by gas including N2O and SiH4, and gas flow ratio of N2O to SiH4 ranges from 1 to 50:1, inclusive.

Preferably, the silicon oxide film in the anti-reflection film has a thickness that ranges from 1 nm to 150 nm, inclusive.

Preferably, the silicon nitride film in the anti-reflection film is deposited by using a method of PECVD, APCVD or LPCVD.

Preferably, the silicon nitride film in the anti-reflection film is formed by gas including NH3 and SiH4, and gas flow ratio of NH3 to SiH4 ranges from 1 to 30:1, inclusive.

Preferably, the silicon nitride film in the anti-reflection film has a thickness that ranges from 10 nm to 150 nm, inclusive.

A solar cell manufactured by using the above-mentioned manufacturing method is also provided.

Compared with the prior art, the above-mentioned technical solutions have the following advantages.

According to the technical solutions provided by the embodiments of the invention, the plasma cleaning is firstly performed on the silicon wafer by using the oxidizing gas, so as to form a compact first silicon oxide film on the surface of the silicon wafer while cleaning the silicon wafer; then the anti-reflection film is formed on the surface of the cleaned silicon wafer, i.e., the anti-reflection film is formed on the surface of the first silicon oxide film, where the anti-reflection film includes at least a silicon oxide film. Since the silicon oxide film has a good electrical insulation property and an anti-reflection effect, the solar cell manufactured by using the manufacturing method provided by the embodiments of the invention has a good electrical insulation property with the packaging material and the glass substrate, so the corresponding photovoltaic module has an anti potential induced degradation effect, which improves the electrical performance of the photovoltaic module operating under the high negative voltage for a long time.

### BRIEF DESCRIPTION OF THE DRAWINGS

The accompanying drawings needed to be used in the description of the embodiments or the prior art will be described briefly as follows, so that the technical solutions according to the embodiments of the present invention or according to the prior art will become clearer. It is obvious that the accompanying drawings in the following description are only some embodiments of the present invention. For those skilled in the art, other accompanying drawings may be obtained according to these accompanying drawings without any creative work.

FIG. 1 is a schematic flowchart of a method for manufacturing a solar cell according to an embodiment of the invention; and

FIGS. 2 to 7 are sectional views of the solar cell during the manufacturing method according to embodiments of the invention.

### DETAILED DESCRIPTION OF THE INVENTION

As described in the background, in the photovoltaic module manufactured by using the existing solar cell manufacturing processes, the potential induced degradation effect is prone to occur, so the electrical performance parameters of the photovoltaic module, such as FF, Jsc and Voc are deteriorated and will be lower than the design criteria when the photovoltaic module operates under the high negative voltage for a long time.

The inventor has found that there are mainly two reasons which cause the potential induced degradation effect, one is related to the photovoltaic module system and the other is related to the photovoltaic module.

As for the photovoltaic module system, it is indicated by the research and the actual operation of the power plant that, in a case that all of the photovoltaic modules between the solar cell module in the middle of the solar cell module array and the negative output terminal of the inverter operate under negative bias, the closer the solar cell module is to the negative output terminal of the inverter, the stronger the potential induced degradation effect is; and in a case that all of the modules between the solar cell module in the middle of the solar cell module array and the positive output terminal of the inverter operate under positive bias, the potential induced degradation effect is not obvious. Whether the solar cell module and the solar cell thereof operate under the positive bias or the negative bias is depended on the grounding mode of the photovoltaic module system and the position of the photovoltaic module in the solar cell module array.

As for the photovoltaic module, external environmental conditions, such as temperature and humidity, may cause leakage current passages to be formed among the packaging material, the glass backboard, the glass substrate and the packaging frame of the photovoltaic module, and thus the leakage current is formed between the solar cell and the grounding frame. Therefore, the electrical performance parameters of the photovoltaic module, such as the fill factor FF, the short-circuit current Jsc and the open circuit voltage Voc are deteriorated, and thus the electrical performance of the photovoltaic module will be lower than the design criteria.

The inventor has also found that the method for reducing the potential induced degradation effect of the photovoltaic module in the prior art is mainly to use packaging material with high body resistance and good quality. Although this method can reduced the potential induced degradation effect to some extent, the cost of the photovoltaic module is greatly increased.

Based on the above-mentioned researches, a solar cell of anti potential induced degradation and a manufacturing method thereof are provided according to the embodiments of the invention. The method for manufacturing the solar cell includes:

performing plasma cleaning on a silicon wafer by using an oxidizing gas, so as to form a first silicon oxide film on the surface of the silicon wafer; and

forming an anti-reflection film on the surface of the first silicon oxide film, where the anti-reflection film includes at least a silicon oxide film.

In the technical solution provided by the embodiments of the invention, the good electrical insulation property of the silicon oxide film is utilized. The plasma cleaning is firstly performed on the silicon wafer by using the oxidizing gas, so as to form a compact first silicon oxide film on the surface of the silicon wafer while cleaning the silicon wafer. Then, the anti-reflection film is formed on the surface of the cleaned silicon wafer, i.e., the anti-reflection film is formed on the surface of the first silicon oxide film, where the anti-reflection film includes at least a silicon oxide film. Therefore, the solar cell manufactured by using the manufacturing method according to the embodiments of the invention has a good electrical insulation property with the outside structures such as the packaging material and the glass substrate, so the corresponding photovoltaic module has an anti potential induced degradation effect, which improves the electrical performance of the photovoltaic module operating under the high negative voltage for a long time. Moreover, there is no need for a special packaging material, leading to a low cost. Furthermore, the technical solution is also compatible with the conventional manufacturing processes of the solar cell and thus suitable for large-scale production.

To make the above objects, features and advantages of the invention more obvious and easy to be understood, specific embodiments of the invention will be illustrated in detail below in conjunction with the drawings.

More specific details will be set forth in the following descriptions for sufficient understanding of the invention. However, the invention may also be implemented in other ways different from the way described herein, and similar extensions may be made by those skilled in the art without departing from the spirit of the invention. Therefore, the invention is not limited to the specific implementations disclosed hereinafter.

### First Embodiment

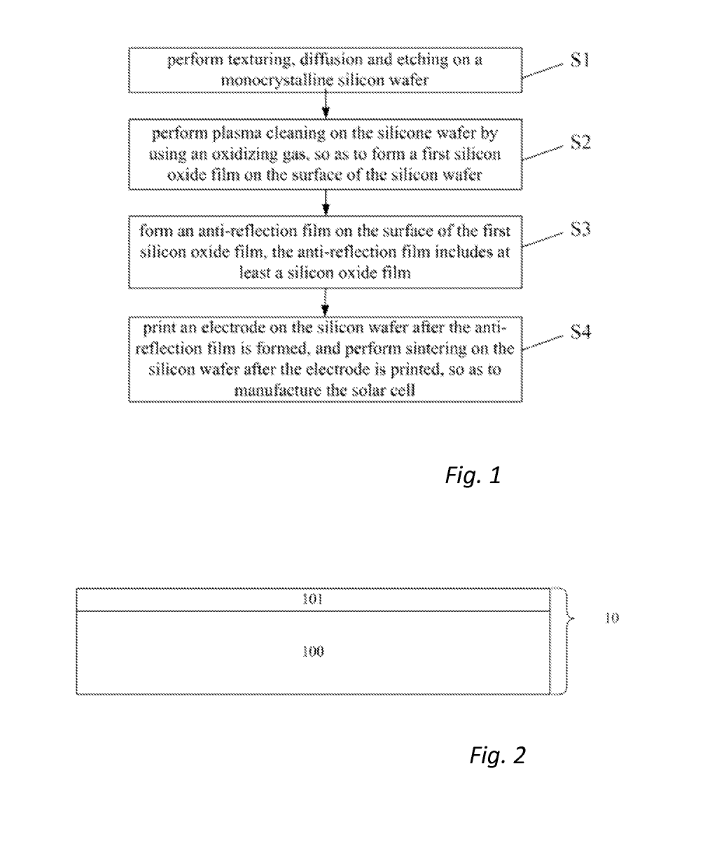

As shown in FIG. 1, a method for manufacturing a solar cell is provided by an embodiment of the invention, including the following steps.

Step S1: performing texturing, diffusion and etching on a monocrystalline silicon wafer. It should be noted that the monocrystalline silicon wafer may be a P-type monocrystalline silicon wafer or an N-type monocrystalline silicon wafer, and it is not limited in the present invention. In the embodiment of the invention, the method for manufacturing the solar cell provided by the invention is described in detail by using the P-type monocrystalline silicon wafer as the monocrystalline silicon wafer as an example. Thus, in an embodiment of the invention, the performing texturing, diffusion and etching on a monocrystalline silicon wafer includes performing acid texturing, phosphorus diffusion and etching on a P-type monocrystalline silicon wafer.

Step S2: performing plasma cleaning on the silicon wafer by using an oxidizing gas, so as to form a first oxide layer film on the surface of the silicon wafer.

After the monocrystalline silicon wafer 100 is etched, the monocrystalline silicon wafer 100 is cleaned by using an oxidizing gas, so as to form a compact first silicon oxide film 101 on the surface of the monocrystalline silicon wafer 100 while removing the impurity on the surface of the monocrystalline silicon wafer 100, as shown in FIG. 2. It should be noted that, in an embodiment of the invention, the oxidizing gas preferably includes at least one of NH3 and N2O, that is, the oxidizing gas is preferably NH3, N2O or combination gas of NH3 and N2O. However, the invention is not limited thereto, as long as the impurity on the surface of the monocrystalline silicon wafer 100 can be removed and the compact first silicon oxide film 101 can be formed on the monocrystalline silicon wafer 100 during the cleaning. Preferably, the plasma cleaning lasts for 30 s to 900 s, inclusive.

Step S3: placing the cleaned monocrystalline silicon wafer 10 into a coating apparatus, introducing a reaction gas into the coating apparatus, and forming an anti-reflection film 20 on the surface of the first silicon oxide film 101, where the anti-reflection film includes at least a silicon oxide film, as shown in FIG. 3.

In the embodiment of the invention, the anti-reflection film 20 may be deposited by using a method of PECVD, APCVD or LPCVD, and the invention is not limited thereto. A commonly-used method for coating the anti-reflection film is PECVD, which mainly includes the following steps. The gas for forming the film is introduced into the coating apparatus. The gas for forming the film is ionized into ions under the action of a RF power supply and a large number of reactive groups are generated after multiple collisions. These reactive groups are absorbed onto the surface of the silicon wafer. The absorbed atoms migrate on the surface of the silicon wafer under the action of their owe kinetic energy and the temperature of the surface of the silicon wafer, and stabilize at the lowest energy point. Meanwhile, the atoms of the surface of the silicon wafer continuously get rid of the binding of the surrounding atoms and enter into the plasmas, to achieve dynamic balance. When the atom deposition speed is faster than the atom escape speed, the desired anti-reflection film can be continuously deposited on the surface of the silicon wafer.

Preferably, in the deposition of the anti-reflection film, the silicon oxide film may be deposited by using a method of PECVD, APCVD or LPCVD. The gas for forming the silicon oxide film includes N2O and SiH4, and the gas flow ratio of N2O to SiH4 ranges from 1 to 50:1, inclusive. It should be noted that, in the deposition of the anti-reflection film, the gas for forming the silicon oxide film may further include NH3, and the gas flow ratio is not limited in the invention and may be determined according a specific process requirement. More preferably, the silicon oxide film has a thickness that ranges from 1 nm to 150 nm, inclusive.

It should be noted that the anti-reflection film 20 may be a single film structure of silicon oxide film, or may be a multi-film structure including a silicon oxide film and a silicon nitride film, so as to improve the light absorption rate of the anti-reflection film and thus improve the photoelectric conversion efficiency of the manufactured solar cell.

Preferably, in the deposition of the anti-reflection film, the silicon nitride film may be deposited by using a method of PECVD, APCVD or LPCVD. The gas for forming the silicon nitride film includes NH3 and SiH4, and the gas flow ratio of NH3 to SiH4 ranges from 1 to 30:1, inclusive. More preferably, the silicon nitride film has a thickness that ranges from 10 nm to 150 nm, inclusive.

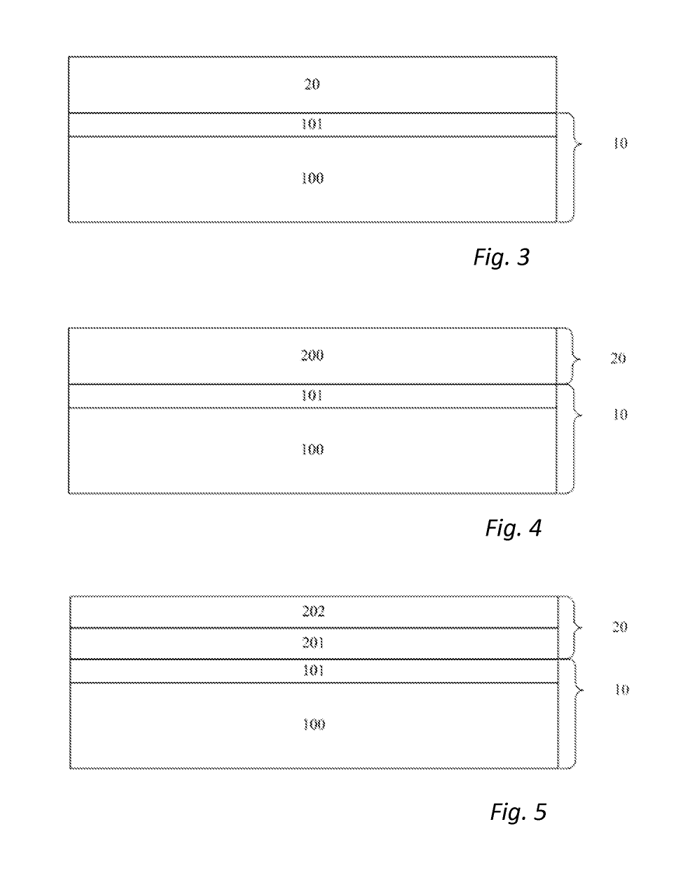

In an embodiment of the present invention, the forming an anti-reflection film 20 on the surface of the first silicon oxide film 101 includes: introducing the gas for forming the silicon oxide film into the coating apparatus, and depositing a uniform silicon oxide film 200 on the surface of the first silicon oxide film 101, so as to form the anti-reflection film 20, as shown in FIG. 4. In a specific example of the embodiment, the gas for forming the silicon oxide film 200 in the anti-reflection film 20 includes N2O and SiH4, where the gas flow rate of N2O is 2000 sccm, and the gas flow rate of SiH4 is 200 sccm. More preferably, the deposited silicon oxide film 200 has a thickness of 70 nm and a refractive index of 1.5.

In another embodiment of the present invention, the forming an anti-reflection film 20 on the surface of the first silicon oxide film 101 includes: introducing the gas for forming the silicon oxide film into the coating apparatus, and depositing a uniform silicon oxide film 201 on the surface of the first silicon oxide film 101; and then introducing the gas for forming the silicon nitride film into the coating apparatus, and depositing a uniform silicon nitride film 202 on the surface of the silicon oxide film 201, so as to form the anti-reflection film 20, as shown in FIG. 5.

In a specific example of the embodiment, the gas for forming the silicon oxide film 201 in the anti-reflection film 20 includes N2O and SiH4, where the gas flow rate of N2O is 2000 sccm, and the gas flow rate of SiH4 is 200 sccm. More preferably, the deposited silicon oxide film 201 has a thickness of 10 nm and a refractive index of 1.5. Moreover, the gas for forming the silicon nitride film 202 in the anti-reflection film 20 includes NH3 and SiH4, where the gas flow rate of NH3 is 6000 sccm, and the gas flow rate of SiH4 is 560 sccm. More preferably, the deposited silicon nitride film 202 has a thickness of 70 nm and a refractive index of 2.06.

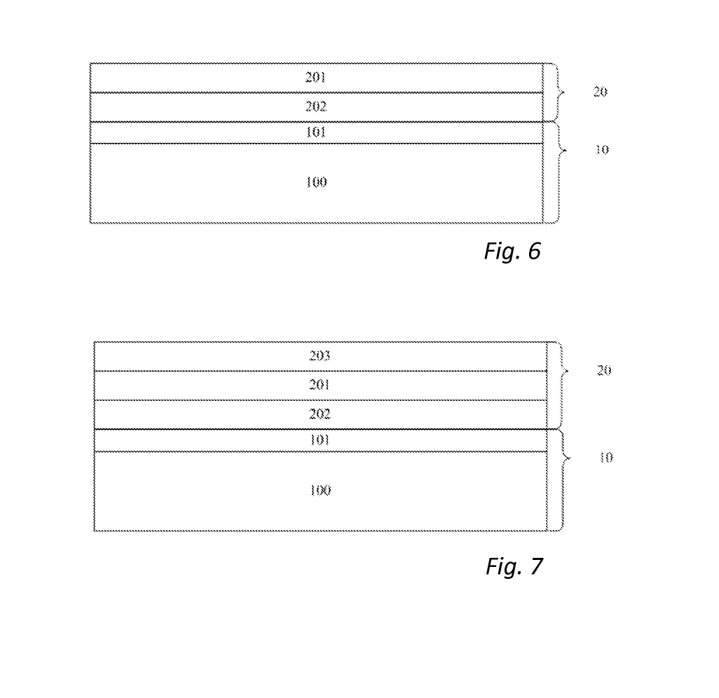

In yet another embodiment of the present invention, the forming an anti-reflection film 20 on the surface of the first silicon oxide film 101 includes: introducing the gas for forming the silicon nitride film into the coating apparatus, and depositing a uniform silicon nitride film 202 on the surface of the first silicon oxide film 101; then introducing the gas for forming the silicon oxide film into the coating apparatus, and depositing a uniform silicon oxide film 201 on the surface of the silicon nitride film 202, so as to form the anti-reflection film 20, as shown in FIG. 6.

In a specific example of the embodiment, the gas for forming the silicon nitride film 202 in the anti-reflection film includes NH3 and SiH4, where the gas flow rate of NH3 is 6000 sccm, and the gas flow rate of SiH4 is 600 sccm. More preferably, the deposited silicon nitride film 202 has a thickness of 70 nm and a refractive index of 2.07. Moreover, the gas for forming the silicon oxide film 201 in the anti-reflection film includes N2O and SiH4, where the gas flow rate of N2O is 2000 sccm, and the gas flow rate of SiH4 is 200 sccm. More preferably, the deposited silicon oxide film 201 has a thickness of 10 nm and a refractive index of 1.5.

In still another embodiment of the present invention, the forming an anti-reflection film 20 on the surface of the first silicon oxide film 101 includes: introducing the gas for forming the silicon oxide film into the coating apparatus, and depositing a uniform silicon oxide film 201 on the surface of the first silicon oxide film 101; then introducing the gas for forming the silicon nitride film into the coating apparatus, and depositing a uniform silicon nitride film 202 on the surface of the silicon oxide film 201; and then introducing again the gas for forming the silicon oxide film into the coating apparatus, and depositing a uniform silicon oxide film 203 on the surface of the silicon nitride film 202, so as to form the anti-reflection film 20, as shown in FIG. 7.

In a specific example of the embodiment, the gas for forming the silicon oxide film 201 located on the side of the silicon nitride film 202 near the silicon wafer 10 includes N2O and SiH4, where the gas flow rate of N2O is 2000 sccm, and the gas flow rate of SiH4 is 200 sccm. More preferably, the deposited silicon oxide film 201 has a thickness of 5 nm and a refractive index of 1.5. Moreover, the gas for forming the silicon nitride film 202 includes NH3 and SiH4, where the gas flow rate of NH3 is 6000 sccm, and the gas flow rate of SiH4 is 560 sccm. More preferably, the deposited silicon nitride film 202 has a thickness of 70 nm and a refractive index of 2.06. Furthermore, the gas for forming the silicon oxide film 203 located on the side of the silicon nitride film 202 far away from the silicon wafer 10 includes N2O and SiH4, where the gas flow rate of N2O is 2000 sccm, and the gas flow rate of SiH4 is 200 sccm. More preferably, the deposited silicon oxide film 203 has a thickness of 10 nm and a refractive index of 1.5.

Step S4: printing an electrode on the silicon wafer after the anti-reflection film 20 is formed, and performing sintering on the silicon wafer after the electrode is printed, so as to manufacture the solar cell.

A solar cell manufactured by using the above-mentioned manufacturing method is also provided by an embodiment of the present invention.

In the method for manufacturing the solar cell provided by the embodiments of the invention, before the anti-reflection film is deposited on the surface of the silicon wafer, the silicon wafer is pre-processed, i.e., the plasma cleaning is performed on the silicon wafer by using an oxidizing gas, so as to form a compact first silicon oxide film on the surface of the silicon wafer while removing the impurity on the surface of the silicon wafer; then the anti-reflection film is formed on the surface of the silicon wafer after the plasma cleaning, i.e., the anti-reflection film is formed on the surface of the first silicon oxide film, where the anti-reflection film includes at least a silicon oxide film. Based on the good electrical insulation property of the silicon oxide film, the solar cell manufactured by using the method is insulated with the packaging material, the glass substrate and the glass backboard. Therefore, even in the case where some charges are accumulated on the surface of the solar cell, there is no leakage current between the solar cell and the grounding frame, so the photovoltaic module including the solar cell has an anti potential induced degradation effect, i.e., the potential induced degradation effect generated when the photovoltaic module operates under the high negative voltage for a long time can be reduced or eliminated, which improves the electrical performance of the photovoltaic module operating under the high negative voltage for a long time. Moreover, there is no need for a special packaging material, leading to a low cost. Furthermore, the technical solution is also compatible with the conventional manufacturing processes of the solar cell and thus suitable for large-scale production.

The various parts of the present invention are described in a progressive manner, with an emphasis placed on explaining the difference between each other. Hence, the same or similar content of one part may also be suitable for other parts.

The description of the embodiments herein enables those skilled in the art to implement or use the present invention. Multiple modifications to the embodiments will be apparent to those skilled in the art, and the general principle herein may be implemented in other embodiments without departing from the spirit or scope of the present invention. Therefore, the present invention will not be limited to the embodiments described herein, but in accordance with the widest scope consistent with the principle and novel features disclosed herein.

1. A method for manufacturing a solar cell of anti potential induced degradation, comprising:
performing plasma cleaning on a silicon wafer by using an oxidizing gas, so as to form a first silicon oxide film on the surface of the silicon wafer; and
forming an anti-reflection film on the surface of the first silicon oxide film, wherein the anti-reflection film comprises at least a silicon oxide film.

2. The method for manufacturing the solar cell of anti potential induced degradation according to claim 1, wherein the oxidizing gas comprises at least one of NH₃ and N₂O.

3. The method for manufacturing the solar cell of anti potential induced degradation according to claim 2, wherein the plasma cleaning lasts for 30 s to 900 s, inclusive.

4. The method for manufacturing the solar cell of anti potential induced degradation according to claim 3, wherein the forming an anti-reflection film on the surface of the first silicon oxide film comprises:
depositing a uniform silicon oxide film on the surface of the first silicon oxide film, so as to form the anti-reflection film; or
depositing a uniform silicon oxide film on the surface of the first silicon oxide film, and depositing a uniform silicon nitride film on the surface of the silicon oxide film, so as to form the anti-reflection film; or
depositing a uniform silicon nitride film on the surface of the first silicon oxide film, and depositing a uniform silicon oxide film on the surface of the silicon nitride film, so as to form the anti-reflection film; or
depositing a uniform silicon oxide film on the surface of the first silicon oxide film, depositing a uniform silicon nitride film on the surface of the silicon oxide film, and depositing a uniform silicon oxide film on the surface of the silicon nitride film, so as to form the anti-reflection film.

5. The method for manufacturing the solar cell of anti potential induced degradation according to claim 4, wherein the silicon oxide film in the anti-reflection film is deposited by using a method of PECVD, APCVD or LPCVD.

6. The method for manufacturing the solar cell of anti potential induced degradation according to claim 5, wherein the silicon oxide film in the anti-reflection film is formed by gas comprising N₂O and SiH₄, and gas flow ratio of N₂O to SiH₄ ranges from 1 to 50:1, inclusive.

7. The method for manufacturing the solar cell of anti potential induced degradation according to claim 6, wherein the silicon oxide film in the anti-reflection film has a thickness that ranges from 1 nm to 150 nm, inclusive.

8. The method for manufacturing the solar cell of anti potential induced degradation according to claim 4, wherein the silicon nitride film in the anti-reflection film is deposited by using a method of PECVD, APCVD or LPCVD.

9. The method for manufacturing the solar cell of anti potential induced degradation according to claim 8, wherein the silicon nitride film in the anti-reflection film is form by gas comprising NH₃ and SiH₄, and gas flow ratio of NH₃ to SiH₄ ranges from 1 to 30:1, inclusive.

10. The method for manufacturing the solar cell of anti potential induced degradation according to claim 9, wherein the silicon nitride film in the anti-reflection film has a thickness that ranges from 10 nm to 150 nm, inclusive.

11. A solar cell, which is manufactured by:
performing plasma cleaning on a silicon wafer by using an oxidizing gas, so as to form a first silicon oxide film on the surface of the silicon wafer; and
forming an anti-reflection film on the surface of the first silicon oxide film, wherein the anti-reflection film comprises at least a silicon oxide film.

12. The solar cell according to claim 11, wherein the oxidizing gas comprises at least one of NH₃ and N₂O.

13. The solar cell according to claim 12, wherein the plasma cleaning lasts for 30 s to 900 s, inclusive.

14. The solar cell according to claim 13, wherein the forming an anti-reflection film on the surface of the first silicon oxide film comprises:
depositing a uniform silicon oxide film on the surface of the first silicon oxide film, so as to form the anti-reflection film; or
depositing a uniform silicon oxide film on the surface of the first silicon oxide film, and depositing a uniform silicon nitride film on the surface of the silicon oxide film, so as to form the anti-reflection film; or
depositing a uniform silicon nitride film on the surface of the first silicon oxide film, and depositing a uniform silicon oxide film on the surface of the silicon nitride film, so as to form the anti-reflection film; or
depositing a uniform silicon oxide film on the surface of the first silicon oxide film, depositing a uniform silicon nitride film on the surface of the silicon oxide film, and depositing a uniform silicon oxide film on the surface of the silicon nitride film, so as to form the anti-reflection film.

15. The solar cell according to claim 14, wherein the silicon oxide film in the anti-reflection film is deposited by using a method of PECVD, APCVD or LPCVD.

16. The solar cell according to claim 15, wherein the silicon oxide film in the anti-reflection film is formed by gas comprising N₂O and SiH₄, and gas flow ratio of N₂O to SiH₄ ranges from 1 to 50:1, inclusive.

17. The solar cell according to claim 16, wherein the silicon oxide film in the anti-reflection film has a thickness that ranges from 1 nm to 150 nm, inclusive.

18. The solar cell according to claim 14, wherein the silicon nitride film in the anti-reflection film is deposited by using a method of PECVD, APCVD or LPCVD.

19. A solar cell, comprising:
a silicon wafer;
a first silicon oxide film, formed on the surface of the silicon wafer by performing plasma cleaning on the silicon wafer; and
an anti-reflection film, formed on the surface of the first silicon oxide film, wherein the anti-reflection film comprises at least a silicon oxide film.

20. The solar cell according to claim 19, wherein
the anti-reflection film comprises: a uniform silicon oxide film deposited on the surface of the first silicon oxide film; or
the anti-reflection film comprises: a uniform silicon oxide film deposited on the surface of the first silicon oxide film, and a uniform silicon nitride film deposited on the surface of the silicon oxide film; or
the anti-reflection film comprises: a uniform silicon nitride film deposited on the surface of the first silicon oxide film, and a uniform silicon oxide film deposited on the surface of the silicon nitride film; or
the anti-reflection film comprises: a uniform silicon oxide film deposited on the surface of the first silicon oxide film, a uniform silicon nitride film deposited on the surface of the silicon oxide film, and a uniform silicon oxide film deposited on the surface of the silicon nitride film.
